(19) United States
(12) Patent Application Publication
(10) Pub. No.: US 2021/0033686 A1
(43) Pub. Date: Feb. 4, 2021

(54) OPTICALLY PUMPED MAGNETOMETER AND RESONANT CELL FOR A PROBE LIGHT

(71) Applicant: COMMISSARIAT À L'ÉNERGIE ATOMIQUE ET AUX ÉNERGIES ALTERNATIVES, Paris (FR)

(72) Inventors: Rafael Garces Malonda, Grenoble (FR); Agustin Palacious Laloy, Grenoble (FR); Serge Gidon, Grenoble (FR)

(21) Appl. No.: 16/939,444

(22) Filed: Jul. 27, 2020

(30) Foreign Application Priority Data
Jul. 29, 2019 (FR) 1908624

(51) Int. Cl. G01R 33/26; G01K 13/00

(52) U.S. Cl. CPC G01R 33/26; G01K 13/00

(57) ABSTRACT

An optically pumped magnetometer, which comprises: an optically resonant cell filled with an atomic gas, the cell having a resonance frequency; an optical source configured to illuminate the cell with: a pumping light under the effect of which the atoms of the atomic gas undergo an atomic transition, the pumping light having a first frequency that is not tuned to the resonance frequency; and a probe light that undergoes polarization variations when it passes through the cell, the probe light having a frequency that is tuned to the resonance frequency and passing through the cell multiple times; a detector configured to take a polarimetric measurement of the probe light having passed through the cell.

### CROSS-REFERENCE TO RELATED APPLICATIONS

This application claims priority from French patent application no. 1908624 filed on Jul. 29, 2019. The content of this application is incorporated herein by reference in its entirety.

### TECHNICAL FIELD

The invention relates to the field of optically pumped magnetometers, and more specifically that of optically pumped magnetometers based on linear effects (Hanle effect, magnetic resonance or parametric resonance). The invention is applicable to the imaging of biomagnetic fields using an array of magnetometers, in particular in magnetocardiography or in magnetoencephalography.

### PRIOR ART

Optically pumped magnetometers use an atomic gas confined in a cell, typically metastable helium or alkaline gases, as sensitive element. These magnetometers, which can assume different configurations, make it possible to go back to the magnetic field by using the following three processes, which take place either sequentially or concomitantly:
1) The use of polarized light sources, typically lasers, makes it possible to prepare atomic states characterized by a certain orientation or alignment of their spins. This process is called “optical pumping” in the field.
2) These atomic states evolve under the effect of the magnetic field, in particular under the Zeeman effect which corresponds to shifts in the energy levels as a function of the magnetic field to which the atoms are subjected.
3) The optical properties of the atomic environment then undergo changes that depend on the state of the atoms. It is thus possible, through an optical measurement, for example through an optical absorption measurement, to go back to the experienced Zeeman shift and to deduce the measurement therefrom of the magnetic field in which the cell is immersed.

Two major categories of optically pumped magnetometers are distinguished based on the type of pumping done.

In the most common category, the pumping is done with a pumping beam emitting a circularly polarized light and the atomic gas acquires a so-called oriented state characterized by a non-nil average value of its magnetic moment along an axis, which is that of propagation of the pumping beam.

In the other category, the pumping is done with a pumping beam emitting a linearly polarized light and the atomic gas acquires a so-called aligned state characterized by a nil value of its magnetic moment, but by a non-nil value of a property of the type (3 F_{z}²−F²) where F is the total kinetic moment and Fz is the kinetic moment along the polarization direction of the pumping beam.

The characterization of the atomic states (step 3 above) can be done according to at least two models:
by measuring the absorption of a beam that is tuned (or very close) to the considered atomic transition (the beam used for the pumping or a beam called “probe” with the same polarization as the beam used for the pumping);
by using a so-called “probe” beam with linear polarization and an offset wavelength relative to the considered atomic transition. Depending on the type of atomic polarization (orientation or alignment), this beam undergoes a change to its polarization (rotation of the polarization plane in the case of the orientation, creation of a circularly polarized component in the case of the alignment) that can be measured by separating two of the polarization states of the beam (the two polarizations at 45° in the case of the orientation, the two circular polarizations in the case of the alignment), then photo-detecting them so as to identify the increase of one of the polarizations relative to the other. This is then called polarimetric measurement.

In both models, the noise limit of the magnetometer frequently comes from the shot noise, which results from the discrete nature of the photons that are photo-detected and is characterized by a flat spectrum and a spectral density that increases with the square root of the intensity of the light. In order to increase the signal-to-noise ratio, it is necessary to increase the signal without increasing the intensity of the probe excessively, since this risks causing a widening of the atomic resonance and a deterioration of the sensitivity to the magnetic field.

To improve the signal-to-noise ratio level, it therefore appears desirable to increase the impact that the atomic properties have on the variations of the light signals that are photo-detected after they pass in the cell.

One possibility to that end is to extend the optical path traveled by the light in the cell containing the atomic gas. However, given that in many applications the size of the sensor must be reduced, this signal gain must be obtained through another method. Another solution consists of causing the light to interact with the atomic medium several times before being detected. Two different strategies have been proposed with this aim, namely the use of cavities with multiple non-resonant passages and the use of optical resonators.

Work done at Princeton University on magnetometers based on atomic orientation and in particular disclosed in the article “Optical rotation in excess of 100 rad generated by Rb vapor in a multipass cell” by S. Li et al., Phys. Rev. A 84, 061403 (2011) has thus demonstrated the possibility of improving the signal-to-noise level by using a multipass cavity in which the light from a probe beam travels through the atomic medium several times. This cavity is a cavity delimited by two off-centered parabolic mirrors, one of which has a small transparent opening in its center. A slightly divergent beam of light is sent through this hole. This beam undergoes a gradual expansion in the cavity, reaches a maximum size, then re-converges until coming out through the same hole. Although this architecture makes it possible to perform a large number of passes and achieve a very significant signal-to-noise gain, the arrangement of the mirrors is fairly complex to achieve. Furthermore, since the beam undergoes a gradual expansion, the first propagation path is so narrow that the atoms located in the volume thereof contribute to the signal in a much more pronounced manner than all the others do. Significantly poorer noise levels than expected are thus obtained.

As reported in the article by H. Crepaz, Li Yuan Ley and R. Dumke, “Cavity enhanced atomic magnetometry”, Sci. Rep. 5, 15448 (2015), the use of an optical resonator was tested in a magnetometer taking an amplitude modulated-nonlinear magneto-optical rotation (AM-NMOR) measurement, for which measurement the rotation of the polarization depends on the intensity of the probe light. This resonant cavity magnetometer consists of a spherical cell filled with cesium atoms arranged between two semitransparent plane-concave mirrors. The use of a cavity having an optical fineness of 12.7 makes it possible to improve the signal to noise ratio by a factor of 17. This result contrasts with the theoretical forecasts, which show an expected increase on the order of the fineness of the cavity.

U.S. Pat. No. 5,982,174 describes an optical medium having a non-reciprocal birefringence effect, in the case at hand an optical fiber, placed in a Fabry-Pérot cavity so as to maximize this effect. The effect used is inherent to the optical medium implemented, and very small relative to that which can be obtained when the state of this medium can be prepared using a method such as optical pumping, which becomes possible in the case of an atomic gas. This type of pumping method requires a pump light beam, tuned to the atomic transition, the aim of which is to prepare the state of the atomic gas so as to maximize the dependency of its birefringence properties relative to the variations in the ambient magnetic field.

When a single beam is used both to make the pump and the probe, which corresponds to the architecture of U.S. Pat, No. 5,982,174, it is not possible to obtain a satisfactory signal gain by adding a Fabry-Pérot cavity. Indeed, when the absorption of the probe is not taken into consideration, a simple mathematical model shows that the signal-to-noise ratio is proportional to the fineness of the optical cavity, that is to

$$\frac{1 + R}{1 - R}$$

where R is the reflectivity of the mirrors that delimit the cavity. In reality, an absorption, even residual, causes a signal loss. Yet when a single beam is used to perform both functions (pump and probe):
either the beam is resonant with an atomic transition, which makes it possible to prepare the state of the atomic gas, but causes a significant absorption of the optical beam upon each pass, which very significantly reduces the signal-to-noise gain obtained by adding the Fabry-Pérot cavity;
or this beam is offset enough relative to the atomic transition not to have this unwanted effect, but then the atomic gas is too weakly pumped, which very significantly reduces the sensitivity of its birefringence properties to the ambient magnetic field.

When a single beam is used both as pump and probe, the gain in terms of signal-to-noise ratio therefore remains very limited in all cases.

### BRIEF DESCRIPTION OF THE INVENTION

The invention aims to propose an optically pumped magnetometer based on linear effects (Hanle effect, magnetic resonance or parametric resonance) and which has an increased signal-to-noise ratio. To achieve this aim, the invention proposes an optically pumped magnetometer comprising an optically resonant cell filled with an atomic gas, said cell having a resonance frequency, and an optical source. The optical source is configured to illuminate said cell with a pumping light under the effect of which the atoms of the atomic gas undergo an atomic transition and a probe light that undergoes polarization variations when passing through the cell. The pumping light has a frequency that is not tuned to the resonance frequency. The probe light has a frequency that is tuned to the resonance frequency and passes through said cell multiple times. A detector takes a polarimetric measurement of the probe light having passed through the cell.

Certain preferred, but non-limiting aspects of this magnetometer are as follows:
said cell comprises mirrors arranged face-to-face and a container of atomic gas between the mirrors;
it further comprises a tuning system for tuning the resonance frequency to the frequency of the probe light;
the tuning system comprises a heating device for heating said cell;
the heating device comprises a heat absorber placed on the cell and a heat source configured to irradiate the heat absorber;
the tuning system further comprises a thermometer coupled to said cell to measure the temperature thereof and a controller configured to control the heating device from the measured temperature;
the pumping light is tuned in terms of wavelength to the center of an atomic ray and the probe light is tuned in terms of wavelength so as to be offset from the center of said atomic ray.
the detector comprises a polarization analyzer configured to take a measurement of the right circular polarization and the left circular polarization of the probe light having passed through the cell;
the polarization analyzer is configured to take a differential measurement of said right and left polarizations;
it further comprises a parametric resonance excitation circuit configured so as to induce a radiofrequency field modulation in the cell;
the pumping light is linearly polarized.

### BRIEF DESCRIPTION OF THE DRAWINGS

Other aspects, aims, advantages and features of the invention will better appear upon reading the following detailed description of preferred embodiments thereof, provided as a non-limiting example, and done in reference to the appended drawings, in which:

FIG. 1 is a diagram of a magnetometer according to the invention;

FIG. 2 is a diagram of an optically resonant cell that can be used in a magnetometer according to the invention;

FIG. 3 is a diagram of means that can be implemented to adjust the resonance frequency of the optically resonant cell.

### DETAILED DESCRIPTION

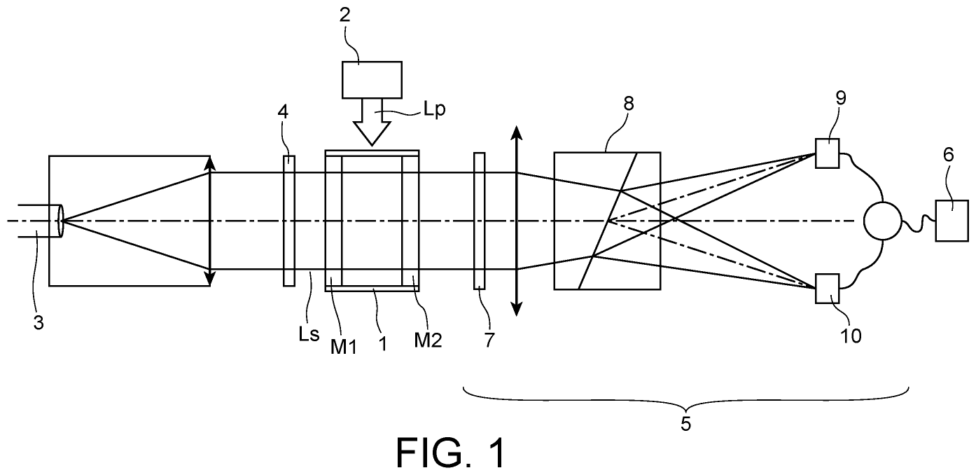

In reference to FIG. 1, the invention relates to an optically pumped magnetometer that comprises a cell 1 filled with an atomic gas, for example helium-4 or an alkaline gas, and that is subject to an ambient magnetic field B₀. In the context of the invention, the cell is optically resonant (it forms a Fabry-Pérot resonator) and has a resonance frequency. As will be described in detail later, the cell may comprise mirrors M1, M2 arranged face-to-face and a container of atomic gas between the mirrors.

In the case where the sensitive element is helium-4, the magnetometer 10 further comprises a system for applying, using two electrodes coupled to the cell, a high-frequency discharge so as to bring the atoms of the atomic gas into an energy state where they are able to undergo an atomic transition, typically in the metastable state 2³S₁.

The magnetometer comprises an optical source configured to illuminate said cell 1 with both a pumping light Lp under the effect of which the atoms of the atomic gas undergo an atomic transition and a probe light Ls that will undergo polarization variations (and optionally absorptions) when passing through the cell. This optical source may comprise a first unit 2 configured to illuminate said cell 1 with the pumping light Lp and a second unit 3 configured to illuminate said cell 1 with the probe light Ls.

The pumping light Lp has a first frequency that is not tuned to the resonance frequency of the optically resonant cavity. In order for the atoms of the atomic gas to undergo the atomic transition, the pumping light can be tuned in terms of wavelength to the center of an atomic transition ray, for example the ray D₀ at 1083 nm in the case of the helium-4. The pumping light can be emitted by a laser source and polarized using a polarizer inserted between the light source and the cell or integrated directly into the laser source 2.

In one preferred embodiment, the pumping light is linearly polarized. As described in the article by F. Beato et al. titled “Theory of a ⁴He parametric-resonance magnetometer based on atomic alignment,” Physical Review A 98, 053431 (2018), magnetometers performing pumping based on linear polarization have significant advantages relative to magnetometers performing pumping based on circular polarization. These advantages are in particular a better resolution on certain measurement axes and a lower sensitivity to unwanted phenomena, in particular the phenomena referred to as “light-shift” or “AC-Stark shift” according to which a light that is circularly polarized and not perfectly tuned to an atomic transition behaves like a fictitious magnetic field disrupting the behavior of the atoms. These advantages make these aligned magnetometers particularly interesting for the imaging of biomagnetic fields using an array of magnetometers, in particular in magnetocardiography or in magnetoencephalography.

In one alternative embodiment, the pumping light can nevertheless be circularly polarized.

The second unit 3 of the optical source is configured to illuminate said cell 1 with a linearly polarized probe light Ls that will undergo polarization variations when it passes through the cell (rotation of the polarization plane in the case of a pumping of the atoms is orientation using a circularly polarized pumping light, creation of a circularly polarized component in the case of a pumping of the atoms in alignment using a linearly polarized pumping light).

The probe light Ls can be emitted by a laser source and polarized using a polarizer 4 inserted between the light source and the cell or integrated directly into the laser source 2.

The probe light Ls has a frequency that is tuned to the resonance frequency of the optically resonant cell. The probe light Ls is incident on the cell so as to pass through said cell multiple times while being reflected by the mirrors.

With the configuration previously described, the non-resonant pumping light can be tuned exactly in terms of length to the center of the atomic ray of interest so that the efficiency of the pumping is maximal, while the resonant probe light can be offset from the center of this ray so as not to also pump the atoms and thus to avoid the loss of signal due to the absorption.

The magnetometer according to the invention also comprises a detector 5 that receives the probe light having passed through the cell and delivers a signal carrying information relative to the state (of alignment or orientation) of the atoms of the atomic gas in the cell to processing electronics 6 that use this signal to provide a measurement of the ambient magnetic field B₀. The detector 5 is more specifically configured to take a polarimetric measurement of the probe light having passed through the cell. When the pumping light is linearly polarized, the detector is configured to detect the circular polarization components. When the pumping light is circularly polarized, the detector can be configured to detect the two components at 45° and to deduce the rotation of the polarization plane therefrom.

Taking the example of a pumping based on linear polarization, the detector 5 is configured to separate, spatially or temporally, the right circular polarization and the left circular polarization of the probe light having passed through the cell.

The detector can thus comprise a quarter-wave plate 7, a separator cube 8 able to separate spatially, over a first and second path, the right circular polarization and the left circular polarization of the probe light having passed through the cell and a photodetector 9, 10 on each of the first and second paths. The difference between the photo-detected signals is supplied to the processing electronics 6.

Alternatively, the detector 5 may comprise only one photodetector. In this alternative embodiment, it is necessary to successively select before photo-detection one, then the other of the two polarizations on which the signal is analyzed. Such a temporal separation of the two polarizations can for example be done by a photo-elastic modulator. In order to maintain a significant bandwidth in the magnetic measurement, this modulator must be excited at a high enough frequency, typically greater than several kHz. This embodiment can prove interesting in certain applications by making it possible not to have to detect two beams at once and therefore further eliminating the difficulty of balancing the two paths. Furthermore, it also has the advantage of reducing the impact that the low-frequency noise of the laser may have on the magnetic measurement.

In one possible embodiment, the magnetometer is a magnetometer based on parametric resonance. It thus also comprises a parametric resonance excitation circuit that comprises a radiofrequency generator that supplies Helmholtz coils with orthogonal axes that surround the cell in order to generate a magnetic field that excites the parametric resonances, also referred to as radiofrequency excitation field. This excitation circuit more specifically generates a radiofrequency magnetic field having two components that are orthogonal to the polarization direction of the pumping light and each oscillating at its own oscillation frequency, namely a component B_{ω} cos Ωt oscillating at the angular frequency ω and a component B_{Ω} cos Ωt oscillating at the angular frequency Ω. These components lead to resonances at each of the oscillation frequencies Ω/2π, ω/2π and to an inter-harmonic of the oscillation frequencies (ω±Ω)/2π, these resonances being associated with the values of the ambient field according to the three directions of a rectangular trihedron.

In another possible embodiment, the magnetometer is a double resonance magnetometer of the type described by G. Di Domenico, H. Saudan, G. Bison, P. Knowles, and A. Weis in “Sensitivity of double resonance alignment magnetometers,” Phys. Rev. A76, 023407 (2007) that also uses a radiofrequency generator and a set of Helmholtz coils to apply a magnetic radiofrequency field that is necessary to induce the magnetic resonance.

In still another embodiment, the magnetometer is a Hanle effect magnetometer that does not need such a set of coils.

A magnetometer according to the invention can also comprise a closed-loop feedback system of the magnetometer to constantly subject the cell to a completely nil magnetic field. The feedback system comprises a regulator coupled to the processing electronics that injects a current into Helmholtz coils with orthogonal axes that surround the cell in order to generate a magnetic compensating field Bc such that the sum Bc+B₀ is kept at zero at all times. Alternatively, the magnetometer can be operated in an open loop, with no compensation for the ambient field.

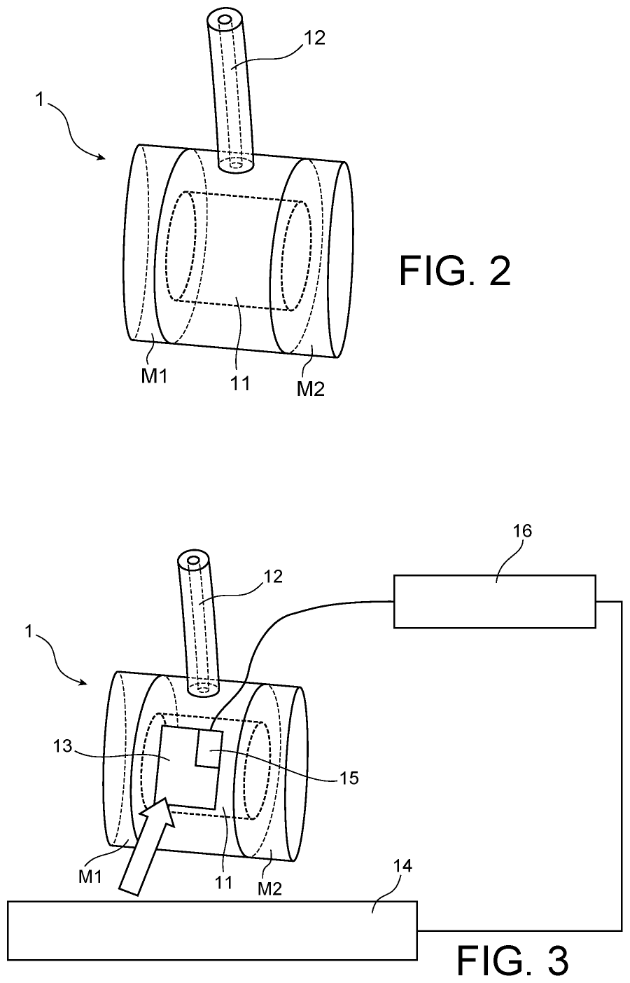

An exemplary embodiment of an optically resonant cavity that can be used in a magnetometer according to the invention is described in detail below in reference to FIG. 2. The cavity 1 comprises a container 11 of atomic gas and mirrors M1, M2 arranged face-to-face on either side of the container. The container and the mirrors can be assembled by molecular bonding. The filling of the container is done conventionally through a duct 12.

The container 11, made from borosilicate, is cylindrical. It has an inner diameter of 10 mm, an outer diameter of 18 mm and a length of 10 mm along an optical axis of the cell. It defines a volume of about 0.8 cm³ of helium-4. The parallelism between its faces orthogonal to the optical axis is ensured to within an arc second.

The duct 12 has a length of 50 mm. It has an outer diameter of 4 mm and an inner diameter of 1.5 mm. It is attached to the middle of the cavity, perpendicular to the optical axis.

The mirrors M1, M2 are made from borosilicate. They have a diameter of 18 mm and a thickness of 6 mm. Their opposite faces are not parallel, but form an angle of 30 arc minutes relative to one another. The inner face of each mirror (container side) bears a reflective coating having a reflectivity of 90% at 1080 nm. Its flatness is less than λ/25. The outer face of each mirror bears an antireflective coating. Its flatness is less than λ/4. In reference to FIG. 3, a magnetometer according to the invention advantageously comprises a tuning system for tuning the resonance frequency of the cell 1 to the frequency of the probe light Ls. This tuning system may comprise a device for heating said cell. This heating device may comprise at least one heat absorber 13 placed on the cell, for example in the form of a black metal film, and a heat source configured to irradiate the heat absorber, for example a fiber laser working in the infrared. Preferably, two heat absorbers are provided on either side of the cell. These absorbers advantageously make it possible to serve as electrodes to apply the high-frequency discharge to the atoms of the atomic gas.

A thermometer 15 arranged alongside said cell makes it possible to measure the temperature thereof. The thermometer 15 is coupled to a controller 16 configured to control the heating device from the measured temperature. The temperature of the cell can thus be controlled with a precision of 0.01° C.

A complete mathematical model of a magnetometer according to the invention, with parametric resonance and alignment pumping, has been developed that comprises:
calculating the evolution of the atomic state under the radiofrequency field B_{ω} cos ωt and the quasi-static field B₀ that one is seeking to measure. The effects of the optical alignment pumping and the depopulation due to the optical pumping are taken into consideration;
the calculation of the signal-to-noise ratio while taking account of the evolution of the polarization of the probe light inside the cell.

An optimal wavelength of the probe light that makes it possible to maximize the signal-to-noise ratio S.N.R. can be determined from the following equation when ┌pump˜┌nat:

$$S \cdot N \cdot R = \frac{\sqrt{h v}}{\sqrt{2 {I}_{0}} γ {J}_{0 , 2} {J}_{1 , 2}} \{ \frac{( R - 3 ) ( R - 1 ) {Γ}_{nat}}{Δ E ( λ )} - \frac{( - 49 + 313 R + 36 {J}_{0 , 2}^{2} {J}_{1 , 2}^{2} ( 1 + 7 R ) ) {Γ}_{nat} Δ E ( λ )}{288 ( R - 1 )} + Γ ( λ ) ( \frac{( 13 + 7 R ) {Γ}_{nat}}{12 Δ E ( λ )} + \frac{( - 361 + 36 {J}_{0 , 2}^{2} {J}_{1 , 2}^{2} ( 17 - 39 R ) + 591 R ) {Γ}_{nat} Δ E ( λ )}{864 {( R - 1 )}^{2}} ) \}$$

where h is the Planck constant, v is the frequency of the probe light, I₀ is the intensity of the probe light, R is the reflectivity (intensity) of the mirrors of the cell, γ is the gyromagnetic ratio, J_{n,s}=Jₙ(s γ B₁/ω) with Jₙ is the Bessel function of the first kind, Γₙₐₜ is the drop-out rate corresponding to the width of the atomic ray, Γₚᵤₘₚ is the dropout rate corresponding to the effect of the pumping light, ┌(λ)=3π rₑ c N | f Re[V(λ)] and ΔE(λ)= 3/2 π rₑ c N | f |m[V(λ)] are respectively the widening and the displacement of the atomic state due to the optical excitation, which depends on the wavelength of the pumping light through the Voigt resonance profile

$$V ( λ ) = \frac{2 \sqrt{Log ( 2 ) / π}}{{r}_{d}} W [ \frac{2 c \sqrt{Log ( 2 ) / π} ( 1 / λ - 1 / {λ}_{r} + {ir}_{n} / 2 )}{{r}_{d}} ] .$$

The Faddeeva function is defined according to W[x]=e^{-x}^{²} (1−Erf[−i x]). Here, rₑ is the conventional ray of the electron, c is the speed of light in vacuum, N is the density of the atomic gas, 1 is the length of the cell, f is the oscillator force of the atomic transition, Γ_{d} is the Doppler width of the ray and Γₙ is the natural ray width.

The following typical parameters are considered for cell filled with helium-4 (20 Torr) operating on the transition D0 and with a reflectivity R=0.9.

| γ | 28 | Hz/nT |
|---|---|---|
| Γₙₐₜ | 10³ | s⁻¹ |
| N | 10¹⁷ | l/m³ |
| l | 0.01 | m |
| f | 0.06 | |
| λᵣ | 1083.205 | nm |
| Γ_{d} | 1.7 × 10⁹ | s⁻¹ |
| Γₙ | 2 × 10⁶ | s⁻¹ |

The optimal wavelength of the probe light is 1083.211±0.002 nm leading to a signal-to-noise ratio, considering that the magnetometer is affected by a shot noise, that is approximately of 0.8 fT/√Hz.

1. An optically pumped magnetometer, comprising:
an optically resonant cell filled with an atomic gas, said cell having a resonance frequency;
an optical source configured to illuminate said cell with:
a pumping light under the effect of which atoms of the atomic gas undergo an atomic transition, the pumping light having a first frequency that is not tuned to the resonance frequency; and
a probe light that undergoes polarization variations when it passes through the cell, the probe light having a frequency that is tuned to the resonance frequency and passing through said cell multiple times;
a detector configured to make a polarimetric measurement of the probe light having passed through the cell.

2. The optically pumped magnetometer according to claim 1, wherein said cell comprises mirrors (M1, M2) arranged face-to-face and a container of the atomic gas between the mirrors.

3. The optically pumped magnetometer according to claim 1, further comprising a tuning system for tuning the resonance frequency to the frequency of the probe light.

4. The optically pumped magnetometer according to claim 3, wherein the tuning system comprises a heating device for heating said cell.

5. The optically pumped magnetometer according to claim 4, wherein the heating device comprises a heat absorber placed on the cell and a heat source configured to irradiate the heat absorber.

6. The optically pumped magnetometer according to claim 4, wherein the tuning system further comprises a thermometer coupled to said cell to measure the temperature thereof and a controller configured to control the heating device from the measured temperature.

7. The optically pumped magnetometer according to claim 1, wherein the pumping light is tuned in terms of wavelength to a center of an atomic ray and the probe light is tuned in terms of wavelength so as to be offset from the center of said atomic ray.

8. The optically pumped magnetometer according to claim 1, wherein the detector comprises a polarization analyzer configured to separate, spatially or temporally, a right circular polarization and a left circular polarization of the probe light having passed through the cell.

9. The optically pumped magnetometer according to claim 8, wherein the polarization analyzer is configured to take a differential measurement of said right and left polarizations.

10. The optically pumped magnetometer according to claim 1, further comprising a parametric resonance excitation circuit configured so as to induce a radiofrequency field modulation in the cell.

11. The optically pumped magnetometer according to claim 1, wherein the pumping light is linearly polarized.
